(19) United States
(12) Patent Application Publication
(10) Pub. No.: US 2006/0131663 A1
(43) Pub. Date: Jun. 22, 2006

(54) Semiconductor device and method for manufacturing the same

(75) Inventor: Nobuji Kobayashi, Gifu (JP)

Correspondence Address: OLIFF & BERRIDGE, PLC, P.O. BOX 19928, ALEXANDRIA, VA, 22320, US

(73) Assignee: Sanyo Electric Co., Ltd., Osaka (JP)

(21) Appl. No.: 11/297,459

(22) Filed: Dec. 9, 2005

(30) Foreign Application Priority Data
Dec. 17, 2004 (JP) 2004-366670

(51) Int. Cl. H01L 29/76

(52) U.S. Cl. 257/374

(57) ABSTRACT

In a transistor, trenches are formed between each of a source region and a drain region and a channel region under the gate electrode at the position sandwiched by them. Ion implantation of impurity is carried out on the surface of the trench to form a low-concentration doped region. When the trench 50 is formed by etching, a projection 70 remains on the bottom thereof. Photoresist 86 is spin-coated on the principal surface of the semiconductor substrate where the trench 50 is formed. An opening for the photoresist 86 is installed at the part corresponding to the trench 50 and, using the photoresist 86 as a mask, ion implantation for the formation of a low-concentration doped region is performed. As a result of formation of a projection 70 in the trench, non-uniformity of film thickness of the photoresist in the trench is reduced.

### BACKGROUND OF THE INVENTION

1. Field of the Invention

The present invention relates to a semiconductor device and to a method for manufacturing the same. More particularly, it relates to a semiconductor device including a transistor structure where a trench is formed between each of a source region and a drain region and a channel region under the gate, and a lightly doped region is formed on the surface of the trench, and also relates to a method for manufacturing the same.

2. Description of the Related Art

Withstand voltage of transistor formed on a semiconductor substrate can be enhanced by adjusting the length of the gate and implantation concentration of impurities into the source region and the drain region. However, when transistors where withstand voltage is different are accumulated on the same semiconductor substrate, there has been a problem that element size of transistors of medium to high withstand voltage are apt to become big.

With regard to such a problem, there has been a proposal of a constitution in which a trench is formed between each of a source region, a drain region and a channel region under gate electrode and, at the same time, an insulator is filled in the trench utilizing technique of STI (shallow trench isolation) as shown in the Patent Document 1 which will be mentioned later.

FIG. 1 is a schematic cross-sectional view of an element for illustrating the structure of a conventional medium withstand voltage transistor element utilizing the STI structure and a method for manufacturing the same. Incidentally, FIG. 1 is a vertical cross-sectional view along the direction of channel of the transistor. In this drawing, the transistor shows the case of an MOS transistor of N channel. This transistor is constituted including a source region 2, a drain region 4, a channel region 6 located between them and a gate electrode 8 controlling the current flowing in the channel. Trenches 10, 12 are formed around the source region 2, drain region 4 and channel region 6. In each of the area between the source channel 2 and the channel region 6, and the area between the drain region 4 and the channel region 6, a trench 10 is formed and a trench 12 is also formed surrounding all of those regions for separation of the element. After formation of the trenches 10, 12, photoresist is spin-coated on the surface of the semiconductor substrate.

FIG. 2 is a schematic cross-sectional view of the element showing the ion implantation which is carried out thereafter. The spin-coated photoresist film 14 is subjected to patterning to form an opening on the trench 10 and, using the photoresist film 14 as a mask, ion implantation of N-type impurity from the opening to the trench 10 is carried out. When the direction for implantation is made oblique, ion implantation is also conducted on the wall of the trench 10 and a lightly doped region (LD region) 18 is formed on the surface of the trench 10 or, in other words, on the wall and bottom of the trench 10. The LD region 18 is called the first region 18a. A structure in which the LD region 18 is formed particularly on the drain is called an LDD (lightly doped drain) structure.

After that, a silicon oxide film 20 is filled in the trenches 10, 12. On the channel region 6, a gate electrode 8 is layered via a gate insulating film 22. Further, after the second region 18b of LD region 18 is formed on the upper surface of the source region 2 and the drain region 4 by ion implantation, a source doped layer 24 and a drain doped layer 26 which are N-type doped layers of higher concentrations are formed. [Patent Document 1] Japanese Patent No. 3,125,752 Size of the trench 10 is set up depending upon the specification of a transistor. For example, size of the trench 10 can be made large in the direction of the channel width corresponding to withstand voltage and current capacity. When size of the trench 10 becomes large, film thickness of the photoresist in the trench 10 is apt to become non-uniform when the photoresist which is used as a mask for ion implantation is spin-coated. For example, as shown in FIG. 3, the photoresist is accumulated in the corner part 30 constituted from wall and bottom of the trench 10 and, compared with the photoresist film thickness at the inner bottom part 32 of the trench 10, a part where the photoresist film thickness is thick can be formed in the corner part. Further, for example, the way in which the photoresist accumulates at the corner part 30 changes depending upon the angle between the direction of the trench 10 and the diameter direction of the semiconductor wafer, and the way accumulation occurs may be different for each of a plurality of elements arranged in one wafer sheet or for each of a plurality of transistors arranged in the same element.

Therefore, in forming an opening in the trench 10 by etching the photoresist film, removal of the photoresist in the trench becomes non-uniform. As a result, in ion implantation forming the first region 18a of the LD region which is conducted thereafter, profile and implanted amount of the impurity become non-uniform, as a result of which there is a problem that a desired transistor characteristic is not achieved.

### SUMMARY OF THE INVENTION

The present invention provides a structure where discrepancies of characteristic are suppressed in a semiconductor device having such a structure that a trench is formed in a semiconductor substrate and impurities are doped into the trench, and also provides a method for manufacturing the same.

The semiconductor device according to the present invention is formed by etching of the principal surface of the semiconductor substrate and has trenches whose side walls and the bottom are doped with impurity, and at least one projection remains on the bottom of the trench in the etching.

A method for the manufacture of a semiconductor device according to the present invention is a method having a step for trench formation where a semiconductor substrate is subjected to etching to form trenches where at least one projection is arranged at the bottom, a filming step where an doping inhibitor against the impurity doping is applied and an impurity doping suppressing film covering the principal surface of the semiconductor substrate in which the trenches are formed is formed, a step for forming an opening where the impurity doping suppressing film in the region corresponding to the trenches is removed and an opening is formed, and a step of impurity doping where the impurities are doped from the opening to the semiconductor substrate and the low-concentration doped region is formed.

### BRIEF DESCRIPTION OF THE DRAWINGS

FIG. 1 is a schematic cross-sectional view of the element illustrating the structure of the conventional medium withstand voltage transistor element utilizing an STI structure and a method for manufacturing the same.

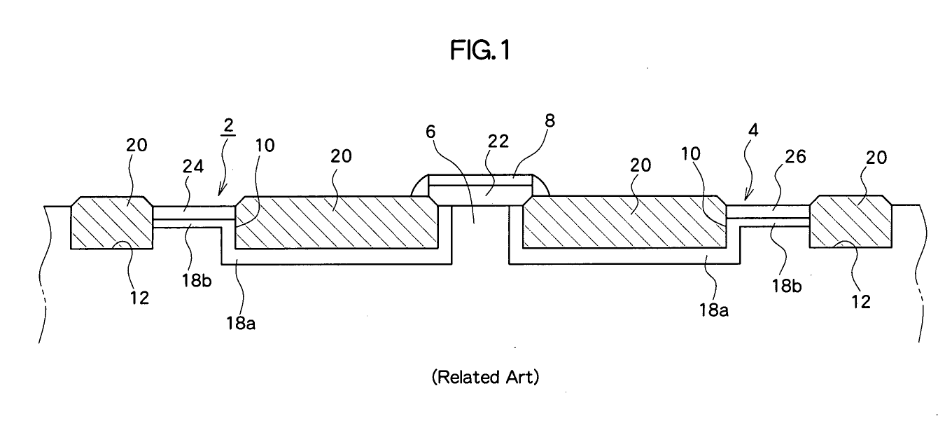

FIG. 2 is a cross-sectional view of the element showing the conventional ion implantation step forming an LD region.

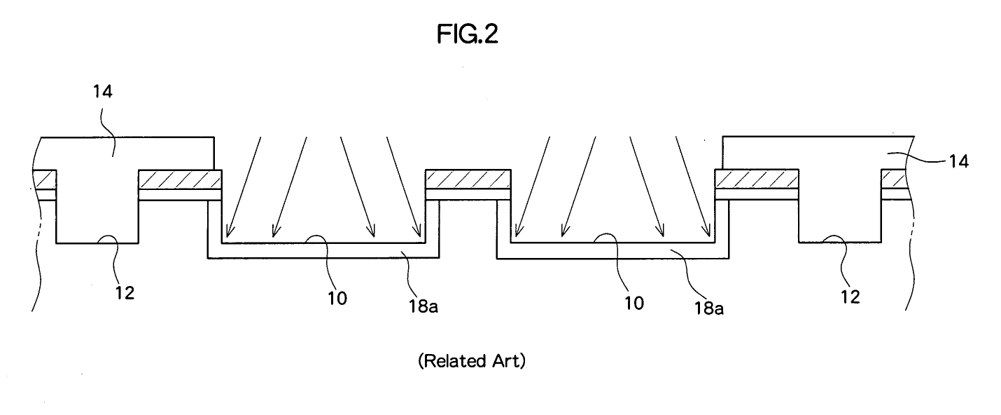

FIG. 3 is a schematic cross-sectional view showing the conventional problem in a state where photoresist which acts as a mask to the ion implantation step forming an LD region is applied.

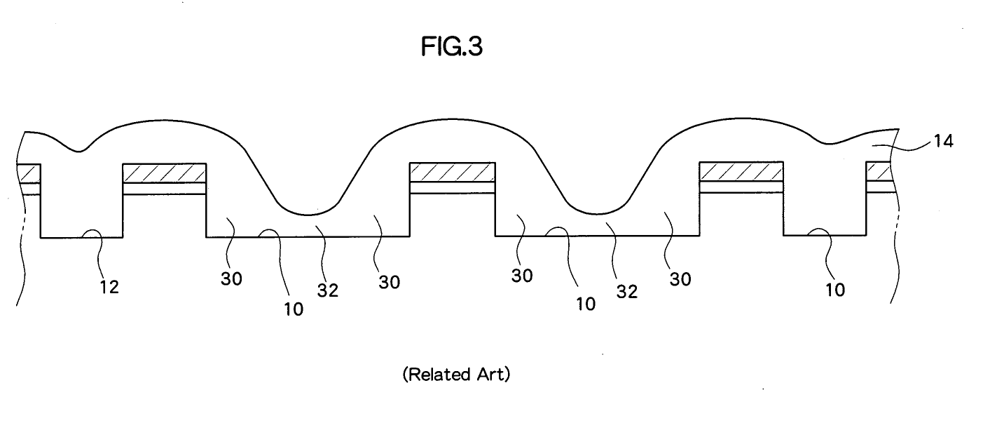

FIG. 4 is a schematic plane view of the element for illustrating the structure of a medium withstand voltage transistor element concerning the present embodiment utilizing an STI structure and a method for manufacturing the same.

FIG. 5 is a schematic cross-sectional view of the element for illustrating the structure of a medium withstand voltage transistor element concerning the present embodiment utilizing an STI structure and a method for manufacturing the same.

FIGS. 6A-6E are schematic vertically cross-sectional views along the channel direction in principal manufacturing steps of the present semiconductor device.

### DESCRIPTION OF THE PREFERRED EMBODIMENTS

As described hereunder, the mode for carrying out the present invention (hereinafter, referred to as embodiment) will be illustrated by referring to the drawings.

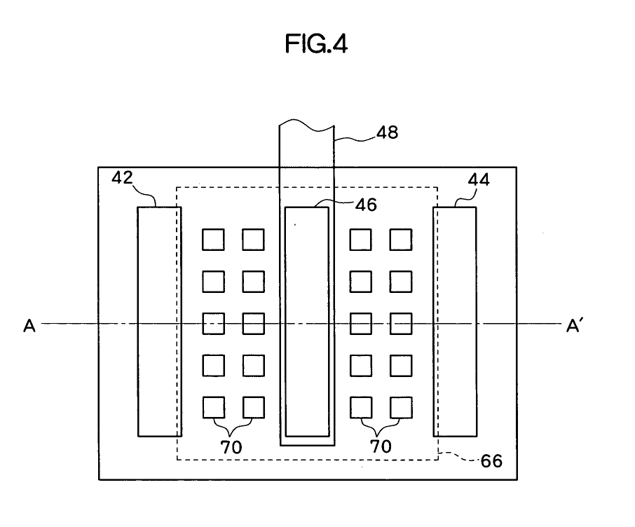

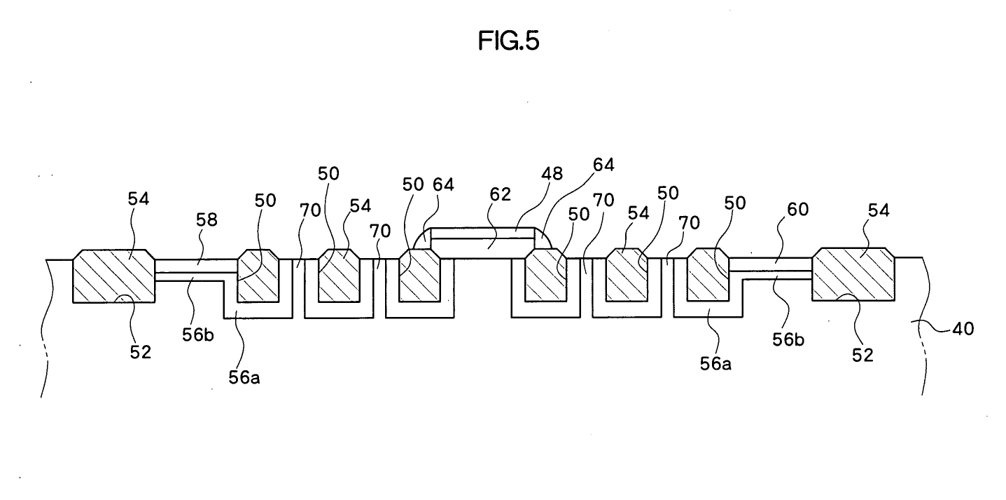

FIG. 4 is a schematic plane view of a medium withstand voltage transistor utilizing an STI structure according to the present invention. FIG. 5 is a schematic vertical cross-sectional view of FIG. 4 along the line A-A′ in the transistor. This transistor is a MOS transistor of N channels and is constituted including a source region 42, drain region 44 and channel region 46 which are formed in a P well 40 formed on the principal surface of the semiconductor substrate, and a gate electrode 48 arranged on the channel region 46. For example, the source region 42, the channel region 46 and the drain region 44 are arranged in one line. Here, its arranging direction is called a channel direction while the direction crossing it is called a channel width direction. The channel region 46 is arranged between the source region 42 and the drain region 44.

Trenches 50, 52 are formed around the source region 42, the drain region 44 and the channel region 46. Trenches 50 are formed between the source region 42 and the channel region 46 and also between the drain region 44 and the channel region 46. At the bottom of the trench 50, plural projections 70 are arranged in a matrix shape along the channel direction and the channel width direction. The trenches 52 are formed surrounding all of those regions and electrically separate the transistor from other elements arranged therearound. Silicon oxide film 54 is filled as an insulator in those trenches 50, 52.

In a P well 40 between the source region 42 and the channel region 46 and between the drain region 44 and the channel region 46, there is formed an LD region 56 where impurity concentration is lower than in the source region 42 and the drain region 44. This LD region 56 comprises a first region 56a along the surface of the trench 50 and a second region 56b along the upper surface of each of the source region 42 and the drain region 44.

On the upper surfaces of the source region 42 and the drain region 44, there are formed a source doped layer 58 and a drain doped layer 60, respectively, on the LD region 56 (the second region 56b) which are doped layers of much higher concentration of N-type. On the channel region 46, a gate electrode 48 is layered via a gate insulation film 62. Further, spacers 64 are formed on the side walls of the gate insulation film 62 and the gate electrode 48.

Incidentally, as a result of having an LD region 56 as mentioned above, withstand voltage between the source region 42 and the drain region 44 in operation of the transistor can be ensured. Moreover, the LD region 56 is connected to the source doped layer 58 and the drain doped layer 60 which are in much higher concentrations and, therefore, their resistance can be reduced whereby operation speed, etc. of the transistor can be advantageously maintained.

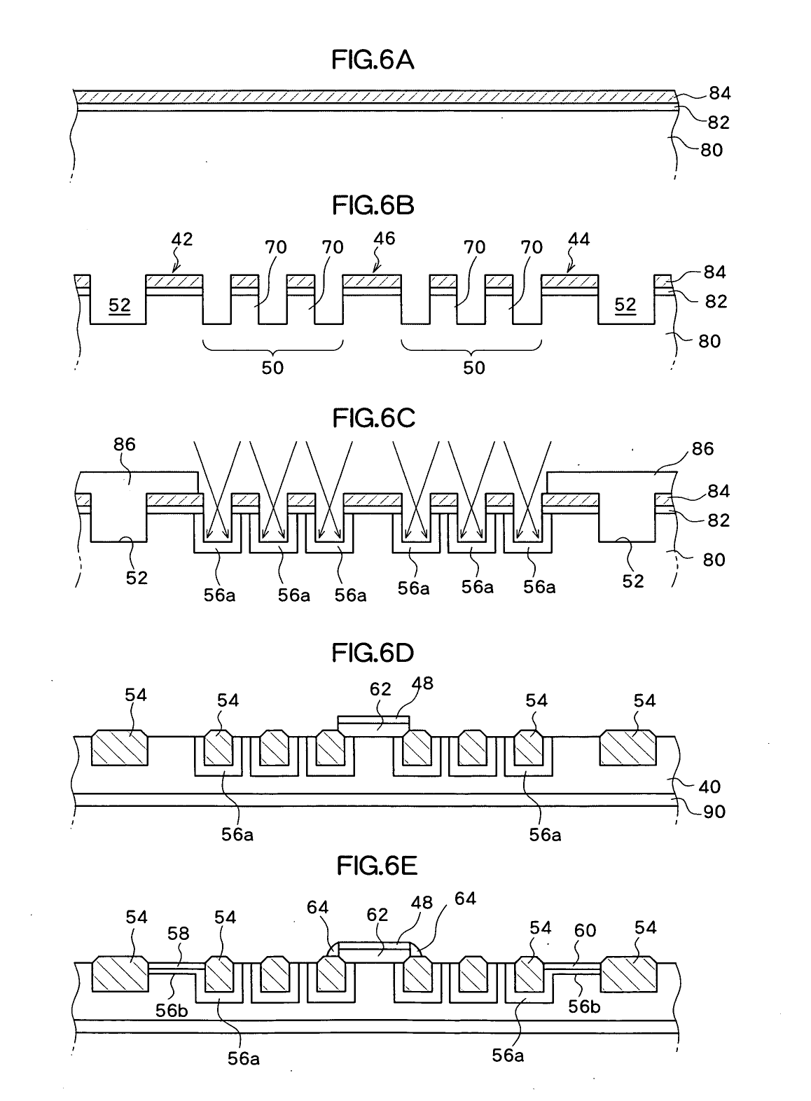

The method for the manufacture of the present semiconductor device will now be illustrated by referring to FIGS. 6A-6E. FIGS. 6A-6E are schematic vertical cross-sectional views of the principal manufacturing steps of the present semiconductor device along the channel direction.

For example, a semiconductor substrate 80 of P-type is used as a semiconductor substrate and, upon it, thermally-oxidized film 82 and silicon nitride film 84 are successively layered (FIG. 6A) After that, in the themally-oxidized film 82 and the silicon nitride film 84, openings are formed on the trench 50, except the projections 70, and on the trench 52, using a lithographic technique. Then the semiconductor substrate 80 is subjected to etching using the thermally-oxidized film 82 and the silicon nitride film 84 as masks, whereupon the trench 50,52 and the projections 70 in the trenches 50 are formed (FIG. 6B).

Photoresist 86 is applied by means of spin coating on the principal surface of the substrate where the trenches 50, 52 are formed and the photoresist is subjected to patterning to form an opening 66 shown in FIG. 4. Impurities of N-type is obliquely implanted to the substrate using the photoresist as a mask to form the first region 56a in the LD region 56 (FIG. 6C).

After formation of the first region 56a of the LD region 56, silicon oxide is deposited on the semiconductor substrate 80. The silicon oxide layer is shaved by means of a chemical mechanical polishing (CMP) using a silicon nitride film 84 as a stopper and the silicon oxide layer 54 filled in the trenches 50, 52 is selectively retained. Further, the silicon nitride film 84 and the thermally-oxidized film 82 are removed by etching.

A deep well 90 and P well 40 are also formed. Further, an insulation film is layered on the semiconductor substrate 80 and it is subjected to patterning to form a gate insulation film 62 at the position corresponding to the channel region 46. After formation of the gate insulation film 62, a gate electrode film is further layered on the semiconductor substrate 80 and this is subjected to patterning to form a gate electrode 48 being arranged on the channel region 46 (FIG. 6D).

Using this gate electrode 48 as a mask, N-type impurities are selectively implanted on the upper surface of each of the source region 42 and drain region 44 to form the second region 56b of the LD region 56. A spacer 64 is also formed by, for example, deposition of silicon oxide film on the semiconductor substrate 80 by a chemical vapor deposition (CVD) followed by subjecting said silicon oxide film to anisotropic etching. Further, N-type impurities are selectively implanted on the upper surface of each of the source region 42 and drain region 44 to form a source doped layer 58 and a drain doped layer 60, respectively (FIG. 6E).

As mentioned above, the present semiconductor device has projections 70 being arranged in the trench 50. The projections 70 damp the flow of photoresist coming to a wall side of the trench 50 when the photoresist 86 is subjected to spin coating and, therefore, the amount of the photoresist 86 stored in a corner part of the trench 50 formed by the wall of the trench 50 and the bottom contacting thereto is reduced. As a result, in each of the plurality of transistors arranged on a semiconductor wafer, a difference in the way of storing the photoresist at the corner part caused by the difference in an angle of each trench 50 to a diameter direction of the wafer can be reduced. In addition, flow of the photoresist is damped by the projections 70, and therefore, difference in thickness of the photoresist 86 in the corner part of the trench 50 and in the inner part thereof is also reduced. Thus, uniformity of thickness of the photoresist 86 in the trench 50 can be achieved. Since non-uniformity of the thickness is reduced as such, remainder of the photoresist 86 after etching at the corner part can be eliminated or reduced in the removal of the photoresist 86 at the part corresponding to the opening 66 by exposing the photoresist 86 to light followed by etching. As a result, it is possible to make the profile and concentration of impurity at the first region 56a of the LD region formed on the surface of the trench 50 by ion implantation uniform, whereby dispersion of characteristics of the transistors can be suppressed.

The projections 70 are formed in such a manner that they do not disturb the ion implantation to the surface (wall and bottom) of the trench 50. For example, a distance between the projection 70 and the wall of the trench 50 and distance between projections 70 are set at a size which is sufficient for the obliquely incoming ions to arrive at the wall or the bottom. On the other hand, the interval between the projections 70 is set narrow to such an extent that an action of making the photoresist hard to flow is achieved taking viscosity, applying conditions, etc. of the photoresist 86 into consideration. In addition, the interval is used as a route for current flowing in the area between the channel region 46 and the source region 42 and also the drain region 44, and therefore, the size of the interval is set taking the influence on characteristics of the transistors into consideration.

As fully illustrated hereinabove, the semiconductor device in accordance with the present invention includes a transistor structure equipped with a source region, drain region and channel region arranged on the principal surface of the semiconductor substrate. Each of the source region and drain region and the channel region are separated from each other by the trench which is formed between them and is filled with an insulating material and, along the surface of the trench, a low-concentration doped region containing lower impurity concentration than the source region and drain region is formed. At the bottom of the trench, at least one projection is arranged.

In a preferred constitution of the present invention, plural aforementioned projections are arranged on the bottom of the trench with intervals in the direction crossing the channel direction as shown in FIG. 4.

The manufacturing method according to the present invention where the semiconductor device is manufactured comprises a step of forming a trench where the semiconductor substrate is subjected to etching to form the trench in which at least one projection is arranged on the bottom, a step of forming a film where an doping inhibitor against the impurity doping is applied to form an impurity doping suppressing film covering the principal surface of the semiconductor substrate in which the trench is formed, a step of forming an opening where the impurity doping suppressing film in the region corresponding to the trench is removed and an opening is formed, and a step of doping the impurities where the impurities are doped from the opening to the semiconductor substrate and the low-concentration doped region is formed.

In a preferred manufacturing method according to the present invention, the plural projections are arranged at positions a predetermined distance apart from the wall of the trench with a predetermined arranging interval between each other. Distance from the wall of the projection is set in such a manner that, in the step of doping the impurities, the impurities can be doped into the wall of the trench and into bottom of the trench between the wall and the projection. The arranging interval for the projections is set in such a manner that, in the impurity doping step, the impurities can be doped into the bottom between the projections.

In the above-mentioned embodiment, illustration was made for a transistor to which the present invention was applied although the present invention can also be applied to elements other than a transistor. Thus, a semiconductor device which is formed by etching the principal surface of a semiconductor substrate and has trenches at a wall and bottom for doping impurities and at least one projection remaining in the bottom of the trench in the etching is also included in the present invention.

In accordance with the present invention as illustrated hereinabove, the projection arranged in the inside of the trench becomes a resistance against flow of a doping inhibitor in the trench during application of the doping inhibitor by means of spin coating or the like, whereby amount of the doping inhibitor retained near the wall of the trench is suppressed and non-uniformity of film thickness of the impurity doping suppressing film in the trench is reduced. As a result, uniformity of removal of the impurity doping suppressing film from the trench is improved and doping the impurities into the trench can be carried out uniformly whereby non-uniformity in the characteristics of the semiconductor device can be suppressed.

What is claimed is:

1. A semiconductor device which includes a transistor structure equipped with a source region, a drain region and a channel region arranged on the principal surface of a semiconductor substrate, respectively, each of the source region and drain region and the channel region being separated from each other by a trench which is formed on the surface of the semiconductor substrate between them and filled with an insulating material and, along the surface of the trench, a low-concentration doped region containing lower impurity concentration than the source region and drain region is formed, characterized in that, at the bottom of the trench, at least one projection is formed.

2. The semiconductor device according to claim 1, wherein plural projections are arranged on the bottom of the trench with intervals in the direction crossing the channel direction.

3. A method for the manufacture of a semiconductor device which includes a transistor structure equipped with a source region, a drain region and a channel region arranged on the principal surface of a semiconductor substrate, respectively, each of the source region and drain region and the channel region being separated from each other by a trench which is formed between them and filled with an insulating material and, along the surface of the trench, a low-concentration doped region containing lower impurity concentration than the source region and drain region is formed, the method comprising:
trench-forming step where the semiconductor substrate is subjected to etching to form the trench in which at least one projection is arranged on the bottom;
film-forming step where an doping inhibitor against the doping impurities is applied to form a impurity doping suppressing film for inhibiting the doping covering the principal surface of the semiconductor substrate in which the trench is formed;
opening-forming step where the impurity doping suppressing film in the region corresponding to the trench is removed and an opening is formed; and impurity-doping step where the impurities are doped from the opening to the semiconductor substrate and the low-concentration doped region is formed.

4. The method for the manufacture of a semiconductor device according to claim 3, wherein
the plural projections are arranged at positions predetermined distance apart from the wall of the trench with a predetermined arranging interval between each other,
the distance from the wall of the projection is set in such a manner that, in the impurity-doping step, the impurities can be doped into the wall of the trench and into a bottom of the trench between said wall and the projection and
the arranging interval for the projections is set in such a manner that, in the impurity-doping step, the impurities can be doped into the bottom of the trench between the projections.

5. The method for the manufacture of a semiconductor device according to claim 3, wherein, in the film-forming step, the doping inhibitor is spin-coated on the semiconductor substrate.

6. A semiconductor device which is characterized in being formed by etching the principal surface of a semiconductor substrate and having trenches at a wall and bottom for ion implantation of impurity, and at least one projection remaining in the bottom of the trench in the etching.
